(19) United States
(12) Patent Application Publication
(10) Pub. No.: US 2009/0273072 A1
(43) Pub. Date: Nov. 5, 2009

(54) SEMICONDUCTOR DEVICE AND METHOD FOR MANUFACTURING THE SAME

(75) Inventors: Tomonari Nakada, Tsurugashima-shi (JP); Nobuyasu Negishi, Tsurugashima-shi (JP); Kazuto Sakemura, Tsurugashima-shi (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION, TOKYO (JP)

(21) Appl. No.: 11/910,377

(22) PCT Filed: Mar. 30, 2006
(86) PCT No.: PCT/JP2006/307288

§ 371 Date: Nov. 14, 2007

(30) Foreign Application Priority Data
Mar. 31, 2005 (JP) 2005-100643

(51) Int. Cl. H01L 23/49; H01L 21/60

(52) U.S. Cl. 257/692; 438/121; 257/E23.024; 257/E21.509; 257/E21.506

(57) ABSTRACT

Disclosed is a semiconductor device eliminated of the effect of an adhesive used in assembling upon the semiconductor chip. According to the semiconductor device, the semiconductor device includes a board, a semiconductor chip provided on and contacting with the board, and a plurality of wires each having both ends firmly fixed to a point close to a peripheral edge of the semiconductor chip and a point on the board close to a peripheral edge respectively. The semiconductor chip is fixed on the board by means of the wires.

### TECHNICAL FIELDS

The present invention relates to a semiconductor device and manufacturing method for same.

### BACKGROUND ART

In the semiconductor device manufacturing method, particularly in the case of mounting a semiconductor chip on a bare board made of glass, alumina or the like, the semiconductor chip if not for use in a high vacuum is bonded on a glass board through an adhesive material generally by use of an adhesive agent or an adhesive sheet. Meanwhile, where using a semiconductor chip in a high vacuum, it is a practice to employ a method that, by using a flit glass as an adhesive material, a semiconductor chip is bonded to the glass board through the flit glass. Where using a semiconductor chip in a high vacuum, package seal is done for the semiconductor device generally by use of a flit glass.

Furthermore, also adopted is a method of joining a glass board and a semiconductor chip together by anodic bonding where mounting a semiconductor chip. Anodic bonding is a technique that, by putting a glass board and a semiconductor chip in close contact, high electric field is applied at an elevated temperature thereby bonding the glass board and the semiconductor chip together. Where joining a glass board and a semiconductor chip together by anodic bonding, the glass board and the semiconductor chip are required to have respective thermal expansion coefficients approximate to each other, thus limiting the glass board materials to which anodic bonding is practically to be applied. Because of no availability of a flit glass suited for sealing with anodic bond glass, the glass with which anodic bonding is available is not adapted for sealing using an ordinary flit glass.

### DISCLOSURE OF THE INVENTION

Where bonding a glass board and a semiconductor chip by use of an adhesive agent or an adhesive sheet, there is a merit that glass board type is not selective. However, an adhesive agent or adhesive sheet contains an organic substance and not preferably used in a high vacuum. Meanwhile, seal process essentially requires a high-temperature process. However, because organic substance carbonizes at a constant temperature or higher, well bonding is not obtainable between the board and the semiconductor.

In conducting bonding using a flit glass, there is not available such a well suited flit glass as to alleviate the difference of thermal expansion coefficient between a glass board and a semiconductor chip, well bonding is not available because breakage readily occurs at the bond surface. The effect of such a thermal expansion coefficient difference can be reduced by decreasing the bond surface to a possible small extent. However, in such a case, because of not obtaining a sufficient strength, the semiconductor chip is readily stripped off in the process of performing wire bonding for electrical connection on the semiconductor chip.

In a solid-state imager using a semiconductor chip, the board is required flat at its chip-mounting surface in order to prevent the positional deviation of a focal point caused by an inclination of the semiconductor chip relative to the board's chip-mounting surface. The general assembling process of the conventional solid-state imager includes dripping a liquid thermo-set adhesive on a board's chip-mounting surface, placing a semiconductor chip thereon, fixing the semiconductor chip by thermally setting the adhesive, and then connecting between the semiconductor chip and the board with metal wires respectively at between bonding pads (electrodes). Due to this, the board and the semiconductor chips are placed in electrical connection, followed by performing sealing at the front surface side by means of a glass cap.

In the conventional structure, the board surface is structured flat. During assembling, a stress is acted in a normal-line direction with respect to the board from the adhesive to the semiconductor chip by the difference of thermal expansion coefficient, due to the following process including the thermal setting after bonding the semiconductor chip. There is a concern that strains occur in the surface of the semiconductor chip to thereby raise crystal defects in the semiconductor chip and image distortion phenomenon unique to the solid-state imager.

Therefore, the problem the invention is to solve includes, as an example, to provide a semiconductor device eliminated of the effect of an adhesive used in assembling upon the semiconductor chip, and a method for manufacturing same.

A semiconductor device in claim 1 is a semiconductor device comprising: a board; a semiconductor chip provided on and contacting with the board; and a plurality of wires each having at least one end firmly fixed to the board in a part close to a peripheral edge of the semiconductor chip and at least a part firmly fixed to the peripheral edge of the semiconductor chip; whereby the semiconductor chip is fixed on the board by means of the wires.

A semiconductor device manufacturing method in claim 12 is a method of manufacturing a semiconductor device whose semiconductor chip is fixed on a board, comprising: a step of supplying a volatile liquid onto the board; a step of placing the semiconductor chip on the volatile liquid and temporarily fixing same; a step of firmly fixing both ends of a wire respectively to a point close to the peripheral edge of the semiconductor chip and a point on the board close to the peripheral edge due to wire bonding; and a step of volatilize the volatile liquid; whereby the semiconductor chip is fixed on the board by means of the wires.

According to the invention, in a semiconductor device having a semiconductor chip mounted on a board formed of glass or the like with electrical connection for operating, the semiconductor chip is fixed on the board only by means of bonding wires.

In the semiconductor device, the bonding pad of the semiconductor chip is higher in position than the bonding pad of the board. The wires fixed on the board are acted upon by a force in a direction pulling the bonding pads of the semiconductor chip thereby the semiconductor chip is fixed to the board.

In the semiconductor device, the wires can be partly or wholly used for electrical connection.

In the semiconductor device, in case the semiconductor chip has a rectangular plan shape, the wires are arranged on two sides or more out of the four sides of the semiconductor chip.

Furthermore, according to a semiconductor device manufacturing method in the invention, in a semiconductor device having a semiconductor chip mounted on a board formed of glass or the like with electrical connection for operating, wherein the semiconductor chip is fixed and mounted on the board by means of bonding wires.

In the semiconductor device manufacturing method, when the semiconductor chip is wire-bonded onto the board, the semiconductor chip is temporarily fixed on the board by use of a volatile liquid. The volatile liquid volatilizes away after the wire bonding, thereby mounting the semiconductor chip on the board only by means of the wires.

The invention is applicable to a semiconductor element such as an electronic emission element, a sensor or a light-emitting element or to a method of mounting same. Meanwhile, application is possible also to a display, an imager, a rendering device, a sensor, a light-emitting device or the like manufactured according to the mounting method. Particularly, the invention can provide a solid-state imager free from the occurrence of image distortion because the occurrence of strain can be prevented in the surface of the semiconductor chip.

According to the invention, the semiconductor chip is mounted on the board by means of the bonding wires without joining with using an adhesive agent or an adhesive sheet or by means of anodic bonding. Accordingly, such impurities are not left as organic substances adversely affecting the in-vacuum operation of the semiconductor device manufactured.

According to the invention, because the semiconductor device is structured by three components of a semiconductor chip, a board and wires, it is compatible with high-temperature process such as seal process.

The wire, used in mounting the semiconductor chip on the board, has a certain degree of elasticity thus enabling to relieve the effect of thermal expansion coefficient difference between the semiconductor chip and the board. Thus, the semiconductor chip and the board are not limited in material. Meanwhile, the wire not serving for electrical connection does not require high electric conductivity, and hence may be, say, of a resin having proper heat resistance or a low-melting glass without limited to a metal material, e.g. gold or aluminum, used in the usual wire bonding. Besides, suitably used is a coating structure of such a metal as stainless steel high in strength and rigidity but low in electric conductivity with a metal material well in bonding capability, e.g. gold or aluminum. Furthermore, it may be structured of a metal coated with the foregoing resin or a glass.

### BRIEF DESCRIPTION OF THE DRAWINGS

FIG. 1 is a schematic magnifying fragmentary sectional view showing a semiconductor device in an embodiment according to the present invention.

FIG. 2 is a schematic magnifying fragmentary sectional view of a board explaining the manufacturing process for a semiconductor device in an embodiment according to the invention.

FIG. 3 is a schematic magnifying fragmentary sectional view of a board explaining the manufacturing process for a semiconductor device in another embodiment according to the invention.

FIG. 4 is a schematic magnifying fragmentary plan view of a board explaining the manufacturing process for a semiconductor device in another embodiment according to the invention.

FIG. 5 is a schematic magnifying fragmentary plan view of a board explaining the manufacturing process for a semiconductor device in another embodiment according to the invention.

FIG. 6 is a schematic magnifying fragmentary sectional view of a board explaining the manufacturing process for a semiconductor device in another embodiment according to the invention.

FIG. 7 is a schematic magnifying fragmentary sectional view of a board explaining the manufacturing process for a semiconductor device in another embodiment according to the invention.

FIG. 8 is a schematic magnifying fragmentary sectional view of a board explaining the manufacturing process for a semiconductor device in another embodiment according to the invention.

FIG. 9 is a schematic magnifying fragmentary sectional view of a board explaining the manufacturing process for a semiconductor device in another embodiment according to the invention.

FIG. 10 is a schematic magnifying fragmentary plan view of a board explaining the manufacturing process for a semiconductor device in another embodiment according to the invention.

### MODE FOR CARRYING OUT THE INVENTION

With reference to the drawings, explanation will be made on embodiments according to the present invention.

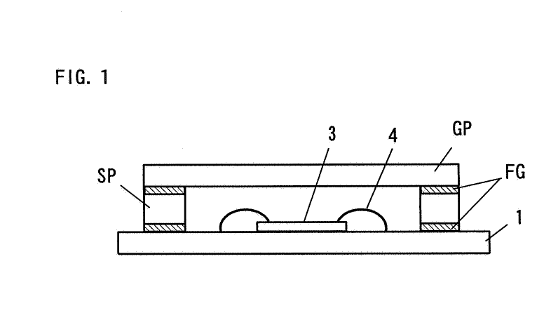

FIG. 1 shows a sectional view of a semiconductor device as an example of an embodiment. The present embodiment is a semiconductor device that mounted on a glass board 1 is a semiconductor chip 3 having a plurality of electron emission elements and the peripheral circuit fabricated on silicon used as a substrate. The semiconductor chip 3 is fixed on the glass board 1 by providing wire bonding to between the electrodes (not shown) patterned on the glass board 1 and the electrodes (not shown) on the semiconductor chip 3. Seal is provided by arranging a spacer frame SP surrounding the semiconductor chip 3 and a glass front plate GP, through use of a flit glass FG. The package thus sealed has an interior provided at vacuum. Electric connection is also given with the wires of between the electrodes patterned on the glass board and the electrodes provided on the semiconductor chip. The elements built on the semiconductor chip are to be driven/controlled by applying a voltage to the patterned electrodes on the glass board.

Besides the silicon substrate, the semiconductor chip to mount on a glass board may be a semiconductor chip based on a substrate of compound semiconductor such as GaAs or SiC, a semiconductor chip based on a substrate of insulator such as sapphire or glass, or a semiconductor chip based on a substrate of metal. Naturally, application is also available in mounting a semiconductor chip whose integrated circuit device is fabricated including light-receiving elements in place of electron emission elements.

The method of mounting a semiconductor chip, according to the invention, is described in the following.

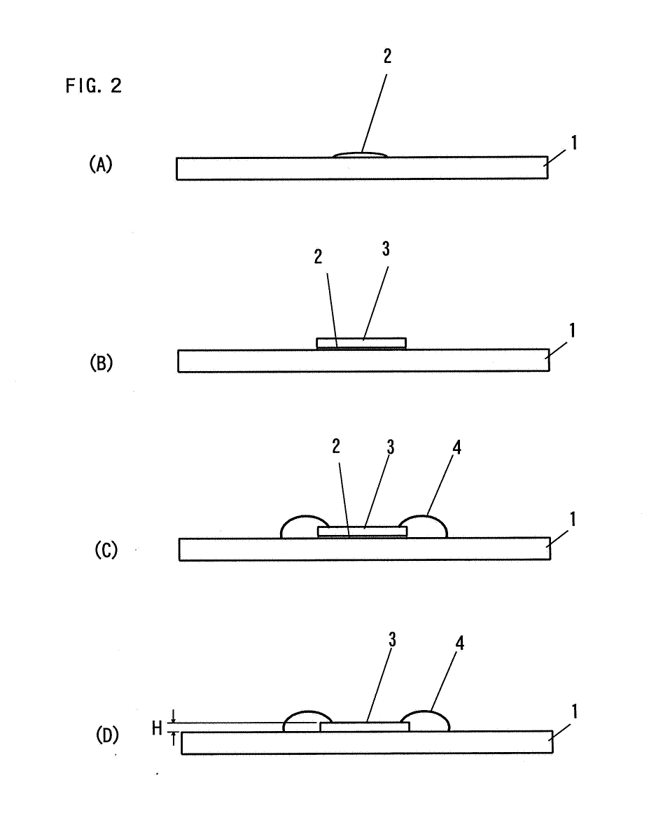

As shown in FIG. 2(A), a volatile liquid 2 is dripped on a glass board 1. As shown in FIG. 2(B), a semiconductor chip 3 is put on the liquid 2 dripped and aligned in position. The semiconductor chip 3 is temporarily fixed on the glass board 1 by the action of surface tension of the liquid 2.

As shown in FIG. 2(C), connection is made by bonding wires 4 to between the electrodes (not shown) of the semiconductor chip 3 temporarily fixed on the glass board 1 and the electrodes (not shown) patterned on the glass board 1.

As shown in FIG. 2(D), by volatilizing the liquid 2 with heating up or so, the semiconductor chip 3 is fixed on the glass board 1 by bonding wires 4.

In this manner, in the present embodiment, a volatile liquid is dripped on the glass board so that the semiconductor chip is temporarily fixed on the glass board by the action of surface tension of the liquid. The volatile liquid is, say, pure water or alcohol.

Connection is not obtainable with accuracy due to vibrations and wire tension as caused upon wire bonding even if merely placing the semiconductor chip on the glass board. However, the semiconductor chip becomes fixed on the glass board through the action of surface tension of the liquid in a certain time after dripping a volatile liquid and placing a semiconductor chip in a mount position. This allows the semiconductor chip and the glass board to be connected together with accuracy by bonding wires. Furthermore, when the volatile liquid volatilizes away after the completion of wire-bonding connection, nothing remains between the semiconductor chip and the glass board, making it possible to implement a preferable mounting without leaving any impurity.

In a semiconductor device whose semiconductor chip is connected by wire bonding on a glass board as shown in FIG. 2(C), in the event the semiconductor chip is acted upon by a displacement force in a direction parallel with or vertical to aboard surface, the force is in a direction toward preventing the displacement because of the elasticity or rigidity of the wires.

Meanwhile, where the other end of the wire 4 closer to the semiconductor chip is arranged in a position distant (distance H) in a normal-line direction from the surface of the board 1 (on which one end of the wire 4 is firmly fixed) as shown in FIG. 2(D), a tension is caused on the wire 4 at between the both ends by firmly fixing the wire 4. A depression force also is acted upon the semiconductor chip 3 in a direction toward the board 1. This makes the fixation more positive.

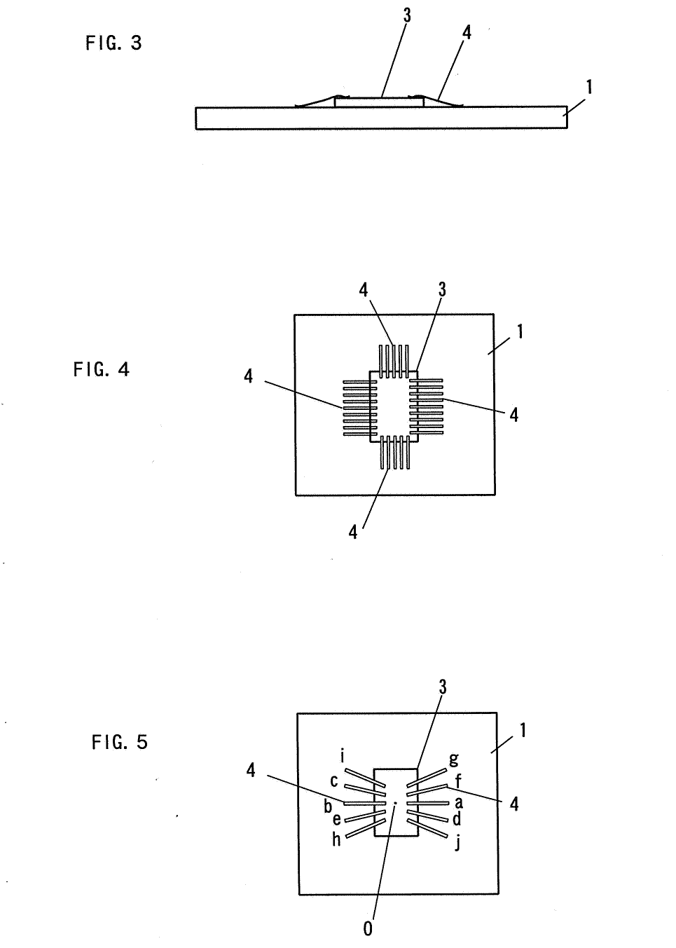

The bonding wires, used upon mounting the semiconductor chip on the glass board, can be used also to electrically connect between the electrodes patterned on the glass board and the semiconductor chip. Where using the wires only in fixing the semiconductor chip, those may be in non-contact with the circuit wiring on the semiconductor chip but in partial contact with the semiconductor chip (at its peripheral edge and its vicinity) as shown in FIG. 3. However, the wires for use in electrical connection are desirably in a loop form as shown in FIG. 2(D) so that those are not in contact with the semiconductor chip in portions excepting at the both ends thereof.

In order to stably mount the semiconductor chip on the glass board, wire bonding is preferably made at all the sides in the case the semiconductor chip is rectangular in plan form as shown in FIG. 4. Nevertheless, wire bonding is not necessarily done at all the sides. For example, by performing wire bonding with the wires positioned obliquely (in plan view) at opposite two sides of the semiconductor chip as shown in FIG. 5, the semiconductor chip can be prevented from positionally deviating in a direction wire bonding has not been done.

In the wire bonding process shown in FIG. 2(C), by performing wire bonding alternately at opposite two sides with one pair of wires instead of first performing wire bonding at one of the opposite two sides with a plurality of wires, the force acting upon the semiconductor chip can be adjusted uniform to prevent against positional deviation. Meanwhile, by performing wire bonding at opposite two sides diagonally about the center of the semiconductor chip with one pair of wires, positional deviation can be prevented. For example, by firmly fixing one pairs of wires in the order of codes a-j at opposite two sides of the semiconductor chip such that those are arranged in positions nearly point-symmetric about the center “0” of the semiconductor chip as shown in FIG. 5, the semiconductor chip can be fixed with positional accuracy maintained high. As shown in FIGS. 4 and 5, one pair out of a plurality of wires 4 opposed is arranged in positions nearly point-symmetric about the center “0” of the semiconductor chip 3.

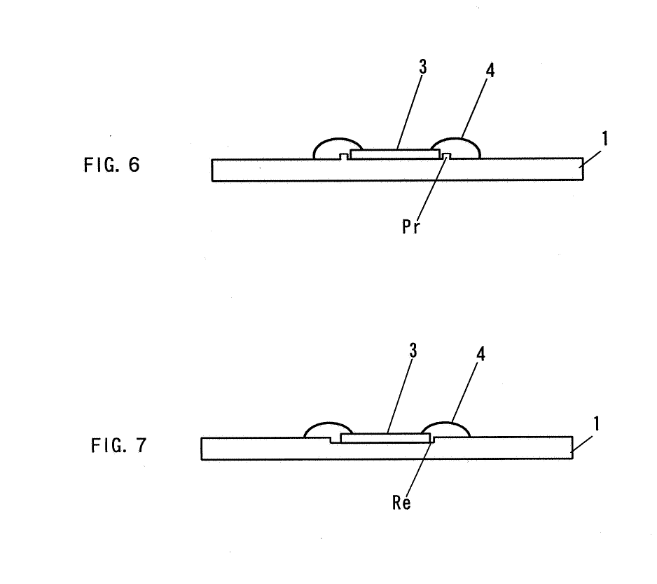

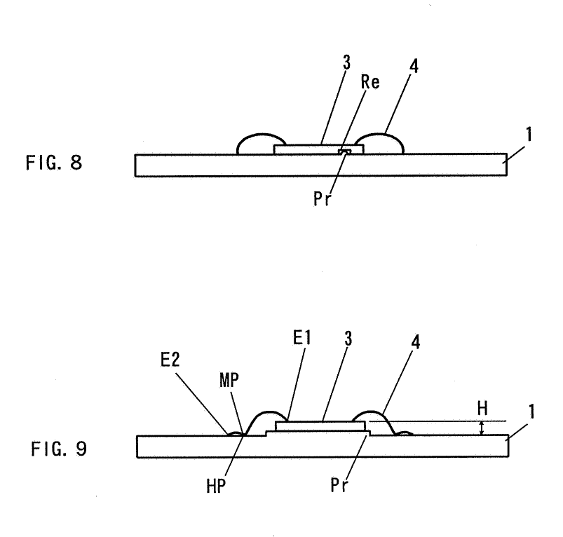

The glass board, on which the semiconductor chip is to be mounted, is satisfactorily not flat. The glass board, if having a step such as a recess or a protrusion as shown in FIGS. 6 to 9, provides such effects as increasing the depression force, simplifying the alignment of the semiconductor chip and preventing the positional deviation of the semiconductor chip. As one example, it is preferable to provide a play-fit region where to restrict the movement of the semiconductor chip 3 on the board 1.

Such a play-fit region can be provided as protrusions Pr such that edges exist on the board in positions between a vicinity of a peripheral edge of the semiconductor chip 3 and a portion of the board in the vicinity thereof as shown in FIG. 6 or as a recess Re as shown in FIG. 7. Furthermore, the play-fit region can be provided as a recess Re or a protrusion Pr in a contact surface between the board 1 and the semiconductor chip 3. In this case, although the protrusion Pr is provided on a board 1 side while the recess Re to be play fit is provided on a semiconductor chip 3 side, those may be vice versa. Furthermore, if within the contact surface, a plurality of plat-fit regions can be provided. By those recesses Re or protrusions Pr and peripheral edge in the board 1 or semiconductor chip 3, the semiconductor chip 3 on the board surface can be restricted from moving.

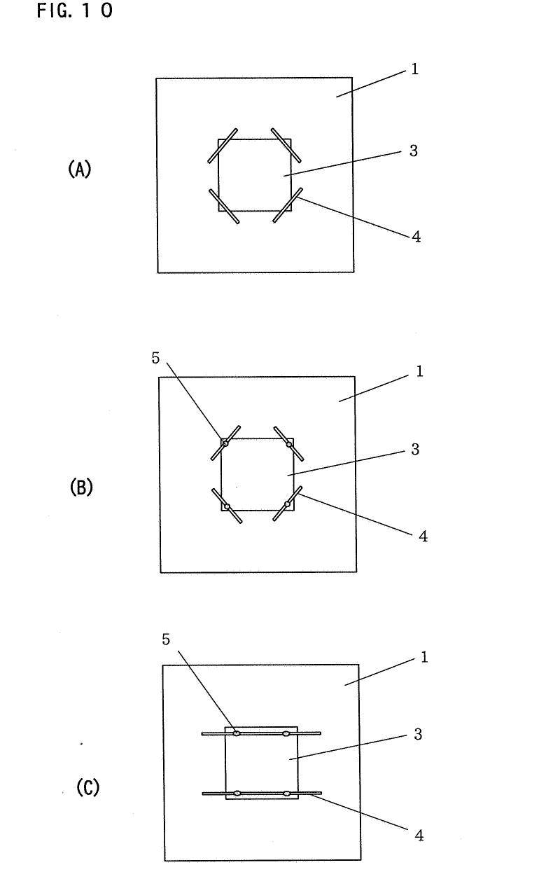

In the wire bonding process shown in FIG. 2(C), the wire 4 can be fixed at its one part MP of between the both ends thereof to a way-stop point HP on the board between the both bonding ends of the wire 4 (E1 close to a peripheral edge of the semiconductor chip 3, its close point E2 on the board 1), as shown in FIG. 9. This causes a further tension on the wire 4 and hence further increases the depression force on the semiconductor chip 3. Meanwhile, in order to further increase the position (distance H) of from the surface of the board 1 at which one end E2 of the wire 4 is secured to the other end E1 distant in a normal-line direction, a protrusion Pr for supporting the entire semiconductor chip 3 can be provided in the board 1, which further increases the force depressing the semiconductor chip 3 on the board 1.

Incidentally, by performing wire bonding such that three wires over the semiconductor chips extend in directions (in plan view) at an angle of approximately 120 degrees, positional deviation can be prevented. Furthermore, after putting the semiconductor chip on a volatile liquid, reinforcement can be provided for temporary fixing of the semiconductor chip 3 with the volatile liquid by firmly fixing first the wire 4 at its both ends in a manner crossing at least apart of the semiconductor chip 3 and contacting therewith as shown in FIG. 10 (A). In this case, it is preferable not to provide a circuit wiring or to provide a circuit-wiring protection film, in a contact portion of the semiconductor chip 3 with the wire 4 crossing over. Furthermore, by previously providing a bonding pad 5 on the semiconductor chip 3 in a position the wire 4 crosses as shown in FIGS. 10 (B) and 10 (C), the wire 4 at its way-stop point may be fixed on the pad 5 after fixing the both end of the wire 4 to the board 1.

This application is based on Japanese Patent Application No. 2005-100643, which is hereby incorporated by reference herein.

1. A semiconductor device comprising:
a board;
a semiconductor chip provided on and contacting with the board; and
a plurality of wires each having at least one end firmly fixed to the board in a part close to a peripheral edge of the semiconductor chip and at least a part firmly fixed to the peripheral edge of the semiconductor chip;
whereby the semiconductor chip is fixed on the board by means of the wires;
a way-stop being provided, to firmly fix a part between both ends of the wire, on the board at between a point close to the peripheral edge of the semiconductor chip and a point on the board close to the peripheral edge to which the both ends of the wire are firmly fixed.

2. A semiconductor device according to claim 1, wherein the plurality of wires, partly or wholly, serves for electrical conduction.

3. A semiconductor device according to claim 1, wherein, in a position distant in a normal-line direction from a surface of the board fixed with the one end of the wire, the wire has another end arranged closer to the semiconductor chip.

4. A semiconductor device according to claim 1, wherein the wires are firmly fixed in a manner to cause a tension on the wire at between both ends.

5. (canceled)

6. A semiconductor device according to claim 1, wherein the wires in a pair are arranged on the board nearly point-symmetrically about a center of the semiconductor chip.

7. A semiconductor device according to claim 6, wherein the wires in a pair, arranged on the board nearly point-symmetrically about a center of the semiconductor chip, are in a plurality arranged on the board nearly point-symmetrically about a center of the semiconductor chip.

8. A semiconductor device according to claim 1, wherein the semiconductor chip is fixed and mounted by the wires due to wire bonding.

9. A semiconductor device according to claim 1, wherein a play-fit region is provided to restrict the semiconductor chip from moving on the board.

10. A semiconductor device according to claim 9, wherein the play-fit region is a recess or a protrusion provided such that the edge exists on the board at between a point close to the peripheral edge of the semiconductor chip and a point on the board close to the peripheral edge to which the both ends of the wire are firmly fixed.

11. A semiconductor device according to claim 9, wherein the play-fit region is a recess or a protrusion provided in a contact surface of between the board and the semiconductor chip.

12. A method of manufacturing a semiconductor device whose semiconductor chip is fixed on a board, comprising:
a step of supplying a volatile liquid onto the board;
a step of placing the semiconductor chip on the volatile liquid and temporarily fixing same;
a step of firmly fixing both ends of a wire respectively to a point close to the peripheral edge of the semiconductor chip and a point on the board close to the peripheral edge due to wire bonding; and
a step of volatilize the volatile liquid;
whereby the semiconductor chip is fixed on the board by means of the wires.

13. A manufacturing method according to claim 12, wherein, in a position distant in a normal-line direction from a surface of the board fixed with the one ends of the wires, the wire has another end arranged closer to the semiconductor chip.

14. A manufacturing method according to claim 12, wherein the wires are firmly fixed in a manner to cause a tension on the wire at between both ends.

15. A manufacturing method according to claim 14, including a step of firmly fixing a part between both ends of the wire, on the board at between a point close to the peripheral edge of the semiconductor chip and a point on the board close to the peripheral edge to which the both ends of the wire are firmly fixed.

16. A manufacturing method according to claim 12, wherein the wires in a pair are arranged on the board nearly point-symmetrically about a center of the semiconductor chip.

17. A manufacturing method according to claim 16, wherein the wires in a pair, arranged on the board nearly point-symmetrically about a center of the semiconductor chip, are in a plurality arranged on the board nearly point-symmetrically about a center of the semiconductor chip.

18. A manufacturing method according to claim 17, wherein a plurality of one pairs of wires are firmly fixed nearly diagonally in position about the center of the semiconductor chip on a one-pair-by-one-pair basis of the wires.
